(19) United States
(12) Patent Application Publication
(10) Pub. No.: US 2007/0120271 A1
(43) Pub. Date: May 31, 2007

(54) Dicing and die bonding adhesive tape

(75) Inventors: Shouhei Kozakai, Annaka-shi (JP); Nobuhiro Ichiroku, Annaka-shi (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd.

(21) Appl. No.: 11/604,800

(22) Filed: Nov. 28, 2006

(30) Foreign Application Priority Data
Nov. 29, 2005 (JP) 2005-343957

(51) Int. Cl. H01L 23/48

(52) U.S. Cl. 257/779

(57) ABSTRACT

A dicing and die bonding tape, comprising a substrate 1, a pressure sensitive adhesive layer (A) 2 superimposed on the substrate 1, a substrate 3 superimposed on the pressure sensitive adhesive layer (A) 2, a pressure sensitive adhesive layer (B) 4 superimposed on the substrate 3, and an adhesive layer 5 super imposed on the pressure sensitive adhesive layer (B) 4, said dicing and die bonding tape having an adhesion strength between the pressure sensitive adhesive layer (A) 2 and a dicing flame of 0.6 N/25 mm or larger, and an adhesion strength between the pressure sensitive adhesive layer (B) 4 and the adhesive layer 5 of from 0.05 to 0.5 N/25 mm.

### CROSS REFERENCE

This application claims benefit of Japanese Patent application No. 2005-343957 filed on Nov. 29, 2005, the contents of which are hereby incorporated by reference.

### FIELD OF THE INVENTION

The present invention relates to a dicing and die bonding tape for manufacturing a semiconductor device which tape has two functions, i.e., fixing a wafer during wafer dicing process, and die bonding a diced chip to a lead frame. Particularly, the present invention relates to a dicing and die bonding tape satisfying both requirements of adhesion strength during dicing process and during picking up of the diced chips.

### BACKGROUND OF THE INVENTION

A semiconductor device is generally prepared by the following processes:

i) fixing a large-diameter silicon wafer on a pressure sensitive adhesive tape called dicing tape,

ii) dicing the wafer,

iii) picking up the diced chip from the dicing tape, and

iv) thermocompression bonding the picked up chip on a lead frame using curable liquid adhesive, i.e., die bonding adhesive.

Recently, a tape used both in the dicing and the die bonding processes, hereinafter referred to as dicing and die bonding tape, has been developed. In the dicing process, the tape is used to fix a silicon wafer and prevent the diced chips from flying off. The diced chip is picked up with an adhesive layer of the tape attached on the chip and then the chip is bonded to a base of a semiconductor device and fixed to the base by curing the adhesive layer.

As a dicing and die bonding tape, Japanese Patent Applications Laid-Open No. 2003-347321 discloses a tape which has a thermoplastic polyimide resin formed on a plastic film substrate. The tape is used in the following manner: Thermocompression bonding a wafer to the polyimide resin layer; Dicing the wafer; Picking up the diced chips with the diced polyimide resin layer attached thereto; Then, thermocompression bonding the chips to a substrate of a semiconductor device. Because the polyimide resin layer is strongly adhered to the wafer, it is difficult to pick up chips. Further, the polyimide resin is thermoplastic, so that an adhesive layer made of the resin is not sufficiently resistant to moisture and high temperature to which the semiconductor device is exposed during wire bonding, encapsulation, and solder reflow processes.

Japanese Patent Application Laid-Open No. 2002-256236 discloses a dicing and die bonding tape comprising a resin layer composed of (A) polyimide resin, (B) epoxy resin, (C) phenolic resin, and (D) curing promoter which is formed on a film substrate. The die bonding layer of the tape comprises a curable epoxy resin to show strong adhesion strength even after being exposed to humid or high temperature. However, picking up of diced chips tends to be difficult to control with the aforesaid dicing and die bonding tape. A reason for this is considered to be as follows: A pressure sensitive adhesive layer of the tape is made from a radiation polymerizable composition comprising (meth)acrylate copolymer, a polymer having (meth)acryl groups or multifunctional acrylic compounds, and a photoinitiator; These components are miscible with the epoxy rein and tends to adhere strongly to the epoxy resin in UV-ray polymerization reaction process or to the softened epoxy resin in thermocompression bonding in the dicing process. The adhesion strength of the pressure sensitive adhesive layer to the die bonding layer tends to change with time, which makes the picking up of the diced chips more difficult.

To solve these problems, Japanese Patent Application Laid-open No. 2004-172180 and No. 2004-349441 by the present inventors disclose a dicing and die bonding tape comprising a substrate such as a polyethylene film, a silicone pressure sensitive adhesive, herein after abbreviated as PSA, layer formed on the substrate, and an adhesive layer comprising (a) a polyimide resin and (b) an epoxy resin, which adhesive layer formed on the PSA layer. The dicing and die bonding tape has stable adhesion strength between the adhesive layer and the PSA layer.

Recently, as packages are getting thinner and higher integrated, silicone dies are getting thinner and larger, so that they are more vulnerable to cracking. One reason for the die cracking is considered to be a big force required to peel an adhesive layer from a PSA layer during picking up diced chips. This problem may be resolved by decreasing adhesion strength of the PSA layer. However, it leads to decreased adhesion strength of the PSA layer to a dicing flame, which may allow diced chips fly off from the tape.

### SUMMARY OF THE INVENTION

An object of the present invention is to provide a dicing and die bonding tape having adhesion strength big enough for preventing diced chips from flying off and adhesion strength mild enough for preventing a wafer from cracking.

Thus, the present invention is a dicing and die bonding tape, comprising a substrate 1, a pressure sensitive adhesive layer (A) 2 superimposed on the substrate 1, a substrate 3 superimposed on the pressure sensitive adhesive layer (A) 2, a pressure sensitive adhesive layer (B) 4 superimposed on the substrate 3, and an adhesive layer 5 super imposed on the pressure sensitive adhesive layer (B) 4, said dicing and die bonding tape having an adhesion strength between the pressure sensitive adhesive layer (A) 2 and a dicing flame of 0.6 N/25 mm or larger, and an adhesion strength between the pressure sensitive adhesive layer (B) 4 and the adhesive layer 5 of from 0.05 to 0.5 N/25 mm.

The aforesaid dicing and die bonding tape meets both requirements for adhesion strength, one strong enough for supporting a wafer during dicing and one mild enough for preventing cracking of the wafer during picking up.

### BRIEF DESCRIPTION OF THE DRAWING

FIG. 1 is a schematic cross-sectional view of the dicing and die bonding tape of the present invention; and

FIG. 2 is a schematic cross-sectional view illustrating a silicon wafer and a dicing frame fixed to the dicing and die bonding tape of the present invention.

### DESCRIPTION OF THE PREFERRED EMBODIMENTS

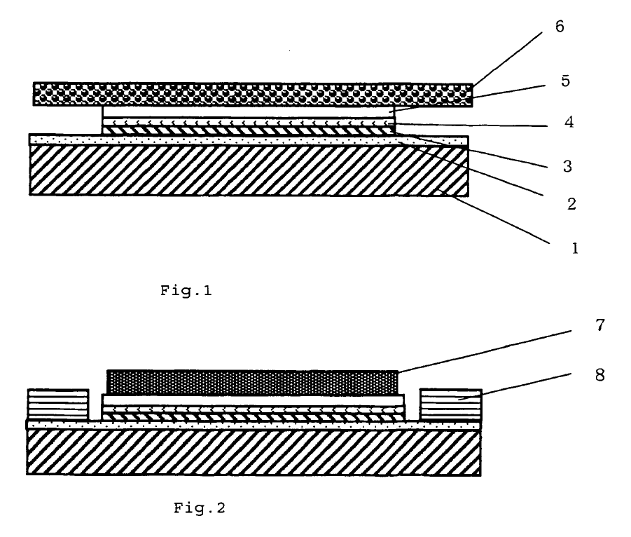

The dicing and die bonding tape of the present invention is explained with reference to the figures. FIG. 1 is a cross sectional view of the present tape. The present tape comprises substrate 1, PSA layer (A) 2 superimposed on substrate 1, substrate 3, PSA layer (B) 4 superimposed on substrate 3, adhesive layer 5, and substrate 6 for adhesive layer 5. In a dicing process, a silicon wafer is placed on adhesive layer 5 after removing substrate 6. A diced silicon chip is picked up with diced adhesive layer adhered thereto. The diced adhesive layer is bonded to a substrate and cured to fix the diced silicon chip. The present tape is characterized in that both PSA layers (A) and (B) have respective adhesion strength. That is, the PSA layer (A) has a adhesion strength of 0.6 N/25 mm to a dicing flame to maintain a silicon wafer during the dicing process, and the PSA layer (B) has a adhesion strength of from 0.05 to 0.5 N/25 mm to the adhesive layer 5 to enable chip picking up without cracking the chip. A PSA layer has cohesive strength larger than strength of adhesion to other material such as an adhesive layer, so that it can be peeled from the adhesive layer without cohesion failure. On the other hand, the adhesive layer has adhesion strength, after heat cured, to a substrate larger than cohesive strength, so that it is ruptured when it is peeled from the substrate. In this context, the term “tape” includes those in the form of a sheet.

Each layer of the present tape is explained in detail.

The substrate 1 may be a film made of polyolefin such as polyethylene, polypropylene, polybutadiene, polybutene, polymethylpentene, or a copolymer thereof; a film made of polyester such as polyethylene terephthalate, polybutylene terephthalate; or a film made of other polymer such as polyvinylchloride, (meth)acrylate copolymer, vinyl acetate copolymer, polyetherketone, polyether/ether/ketone, polyethersulfone, polyamide, polyimide, polyetherimide, polycarbonate or polystyrene. These films may be surface treated with plasma or corona and laminated films of the aforesaid polymer may be used. Considering that the substrate 1 is expanded to separate diced chips for easy pick-up, polyethylene film, polypropylene film and ethylene/propylene copolymer film are preferred.

Thickness of the substrate 1 may be selected depending on modulus of elasticity of the film and a desired expansion. Typically, the substrate 1 has a thickness typically of from 20 to 400 μm, and a thickness of from 30 to 150 μm is preferred.

The PSA layer (A) may be prepared from a known PSA composition showing a strength of adhesion to a dicing flame of 0.6 N/25 mm or larger. For example, rubber PSA compositions, acrylic PSA compositions, or silicone PSA compositions may be used. Acrylic compositions and silicone compositions are preferred. The PSA layer (A) has a thickness preferably of from 5 to 100 μm, more preferably from 10 to 50 μm. A method for determining adhesion strength will be explained later in the specification.

As a dicing flame, a commonly used stainless steel dicing flame may be used. If the PSA layer (A) has strength of adhesion to the dicing flame smaller than 0.6 N/25 mm, the PSA layer (A) may be released from the dicing flame during processes of presser bonding to a silicon wafer or dicing. Preferably, the PSA layer (A) has a strength of adhesion to the dicing flame of 0.8 N/25 mm or larger.

The substrate 3 on which the PSA layer (3) is formed may be composed of the same material as those mentioned for the substrate 1. Polyester film is preferred having softness easy to stretch or deform during a pick up process. Preferably, the film has a thickness of 50 or smaller, more preferably 30 or smaller, most preferably of from 4 to 20. With a film having a thickness larger than the aforesaid thickness, picking up of a chip may be difficult, depending on modulus of elasticity of the film.

The PSA layer (B) formed on the aforesaid substrate 3 has a adhesion strength of from 0.05 to 0.5 N/25 mm, preferably from 0.1 to 0.4 N/25 mm. If the adhesion strength is smaller than the aforesaid lower limit, chips may fly off from the PSA layer (B) in a dicing process. If the adhesion strength is larger than the aforesaid upper limit, picking up of chips may be difficult or a die may crack, the method of adhesion strength measurement will be described later.

A PSA composition for preparing the PSA layer (B) can be selected from those mentioned for the PSA layer (A) according to an adhesive described later in the specification. For an adhesive layer comprising a polyimide resin and an epoxy resin, a silicone type PSA composition is preferred because it is not miscible with those resins. A heat curable PSA silicone composition comprising a linear organopolysiloxane and a solid silicone resin can be used. There are two types of heat curable PSA silicone composition: the first one is cured with an organic peroxide and the second one is cured with a platinum metal compound.

The first type silicone PSA composition comprises a linear organopolysiloxane, an organopolysiloxane copolymer resin composed of (R¹₃SiO_{1/2}) units, wherein R¹ is a substituted or unsubstituted monovalent hydrocarbon group, and (SiO₂) units with a molar ratio of (R¹₃SiO_{1/2}) units to (SiO₂) units ranging from 0.5 to 1.5, and an organic peroxide such as benzoylperoxide, bis(4-methylbenzoyl)peroxide, 2,5-dimethyl-2,5-bis(t-butylperoxy)hexane. The second type PSA composition comprises a linear organopolysiloxane having vinyl groups, the organopolysiloxane copolymer resin described above, and a platinum group metal catalyst such as chloroplatinic acid, alcohol—modified chloroplatinic, a platinum complex with an olefin, a platinum complex with a vinylsiloxane. Preferably the second type PSA composition is used because it can be rapidly cured at a relatively low temperature. By controlling degree of curing, a desired adhesion strength can be attained.

The PSA layer (B) has a thickness of from 5 to 50 μm, preferably from 10 to 30 μm.

The adhesive layer 5 forms a thin film at room temperature having the aforesaid strength of adhesion to the PSA layer (B). Upon heating, the film is softened and then cured. The PSA layer (B) can be peeled from the adhesive layer 5 without being ruptured. Preferably, the adhesive layer is formed from an adhesive composition comprising (a) a polyimide resin, (b) an epoxy resin, and (c) epoxy resin curing catalyst.

In the present invention, the polyimidesilicone resin (a) is composed of a repeating unit represented by the following formula (1) 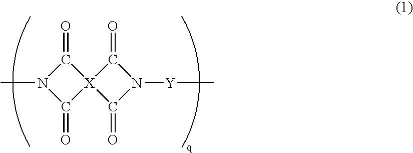
wherein X is a tetravalent organic group, Y is a divalent organic group and q is an integer of from 1 to 300.

The polyimidesilicone resin (a) includes a polyimide resin having a siloxane moiety. That is, the polyimidesilicone resin (a) comprises repeating units with at least one of X and Y comprising siloxane moieties.

A polyamic acid resin composed of repeating units of the following formula (2), which is a precursor of the polyimide, may be used. 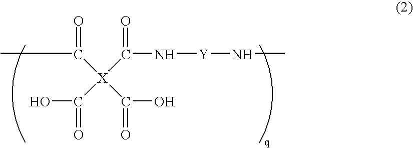
wherein X is a tetravalent organic group, Y is a divalent organic group and q is an integer of from 1 to 300. Preferably, the polyimide resin of the above formula (1) is used because water, which is a by-product of imidization reaction, i.e., ring closure with dehydration, in heat curing process after die bonding, may cause exfoliation at interface between the adhesive composition and a substrate.

In the formulas (1) and (2), q is an integer of from 1 to 300, preferably from 2 to 300, particularly from 5 to 300. A resin with q below the aforesaid lower limit may not provide satisfactory adhesion strength, and a resin with q above the aforesaid upper limit may not be thermocompression bonded well.

The polyimide resin of the formula (1) can be prepared by subjecting the polyamic acid resin of the formula (2) to dehydration and ring closure reaction according to a known method. The polyamic acid can be prepared by subjecting a tetracarboxylic acid dianhydride of the formula (3), 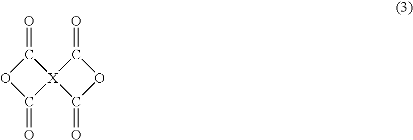
wherein X is as defined above,
to a reaction with about equimolar diamine of the formula (4)
H₂N—Y—NH₂ (4)
wherein Y is as defined above,
in an organic solvent according to a conventional method.

The followings are examples of the tetracarboxylic acid dianhydride of the formula (3). These can be used in a mixture of two or more of them.

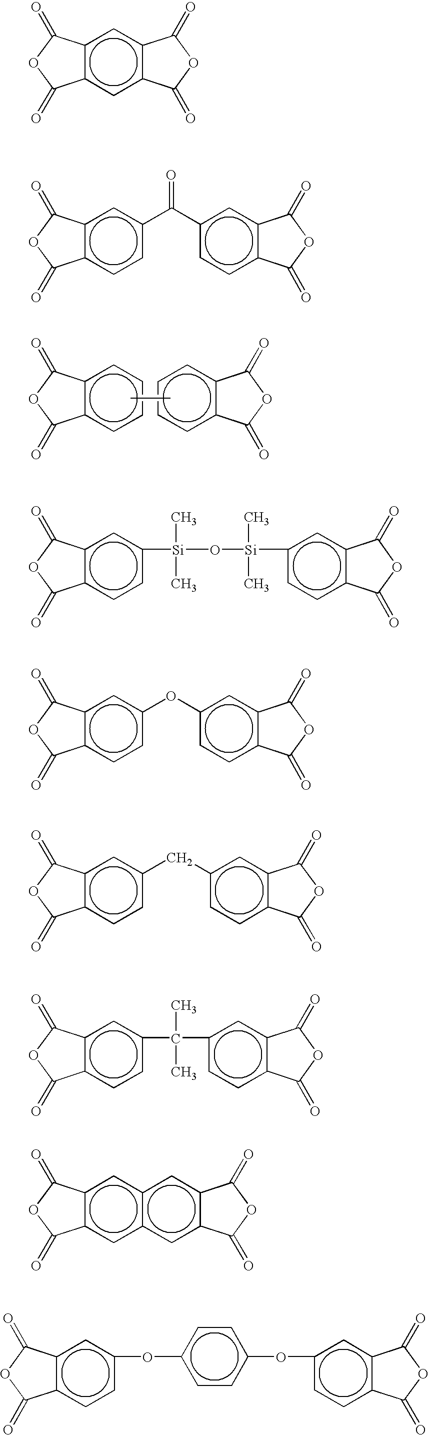

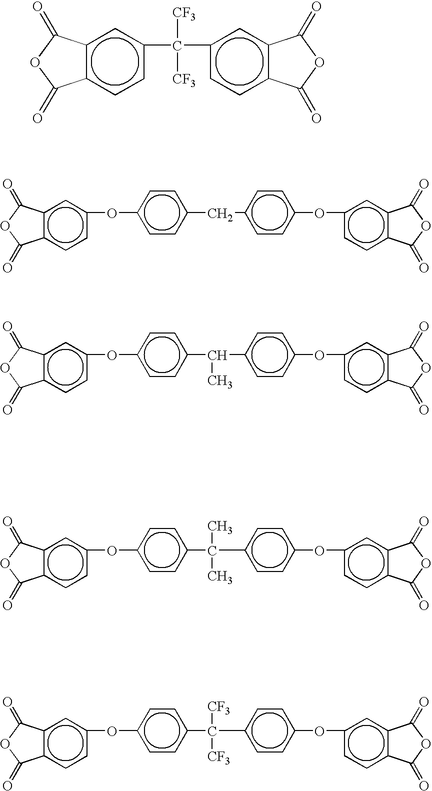

In the diamine of the aforesaid formula (4), it is preferred that 1 to 80 mole %, more preferably from 1 to 50 mole %, of the diamine is the diaminosiloxane compound of the following formula (5) because of good solubility of the resulting polyimide resin in an organic solvent, strong adhesion to a substrate and flexibility of a cured product of the polyimide resin.

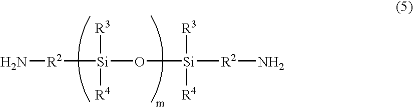

In the formula, R² is a divalent organic group having 3 to 9 carbon atoms, R³ and R⁴ may be the same with or different from each other and are substituted or unsubstituted monovalent hydrocarbon groups having 1 to 8 carbon atoms, and m is an integer of from 1 to 200.

Examples of R² in the formula (5) include divalent groups which may have an ether moiety, for example, alkylene groups such as those of the formulas, —(CH₂)₃—, —(CH₂)₄—, —CH₂CH(CH₃)—, —(CH₂)₆—, and —(CH₂)₈—; and arylene groups as shown below; 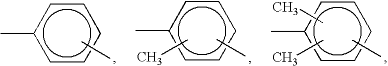
alkarylene groups comprising a combination of alkylene and arylene groups such as benzylene group; oxyalkylene groups such as those of the formulas —(CH₂)₃—O—, and —(CH₂)₄—O; and oxyarylene groups as shown below; and 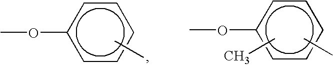
oxyalkarylene groups as the one shown below.

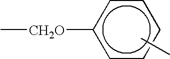

Examples of R³ and R⁴ include alkyl groups such as methyl, ethyl, propyl, isopropyl, butyl, isobutyl, tert-butyl, hexyl, cyclohexyl, 2-ethylhexyl, and octyl groups; alkenyl groups such as vinyl, allyl, propenyl, isopropenyl, butenyl, isobutenyl, and hexenyl groups; aryl groups such as phenyl, tolyl, and xylyl groups; aralkyl groups such as benzyl and phenethyl groups; and halogenated groups thereof, wherein a part or all of the hydrogen atoms bonded to carbon atoms of the above groups is replaced with a halogen atom, such as fluorine, bromine, and chlorine atoms, for instance, chloromethyl, bromoethyl, and 3,3,3-trifluoropropyl groups; among which methyl and phenyl groups are preferred. In the formula (5), m is an integer of from 1 to 200, preferably from 1 to 100, more preferably from 1 to 80.

Examples of the siloxanediamine of the formula (5) are as shown below. These can be used in a mixture of two or more of them.

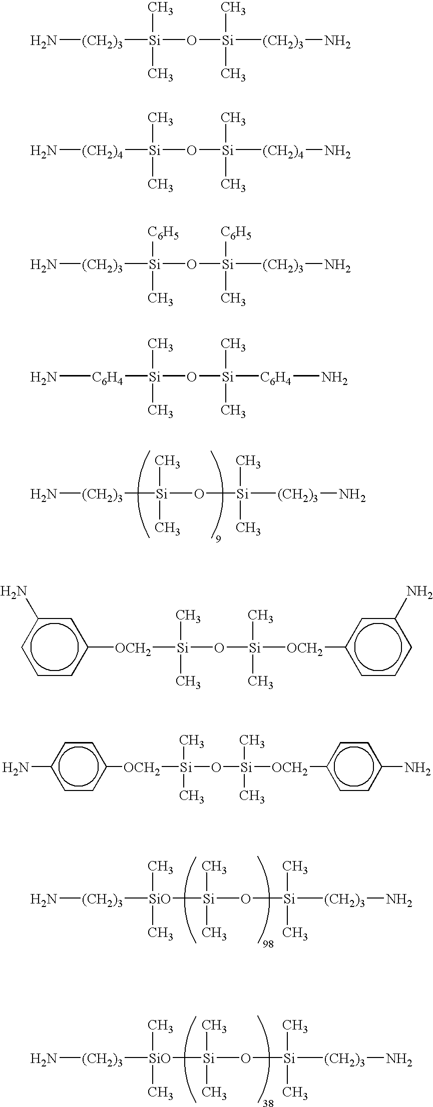

Examples of the diamine of the above formula (4) besides the aforesaid siloxydiamines include aromatic diamines such as p-phenylenediamine, m-phenylenediamine, 4,4′-diaminodiphenylmethane, 4,4′-diaminodiphenyl ether, 2,2′-bis(4-aminophenyl)propane, 4,4′-diaminodiphenylsulfone, 4,4′-diaminodiphenylsulfide, 1,4-bis(3-aminophenoxy)benzene, 1,4-bis(4-aminophenoxy)benzene, 1,4-bis(p-aminophenylsulfonyl)benzene, 1,4-bis(m-aminophenylsulfonyl)benzene, 1,4-bis(p-aminophenylthioether)benzene, 1,4-bis(m-aminophenylthioether)benzene, 2,2-bis[4-(4-aminophenoxy)phenyl]propane, 2,2-bis[3-methyl-4-(4-aminophenoxy)phenyl]propane, 2,2-bis[3-chloro-4-(4-aminophenoxy)phenyl]propane, 1,1-bis[4-(4-aminophenoxy)phenyl]ethane, 1,1-bis[3-methyl-4-(4-aminophenoxy)phenyl]ethane, 1,1-bis[3-chloro-4-(4-aminophenoxy)phenyl]ethane, 1,1-bis[3,5-dimethyl-4-(4-aminophenoxy)phenyl]ethane, bis[4-(4-aminophenoxy)phenyl]methane, bis[3-methyl-4-(4-aminophenoxy)phenyl]methane, bis[3-chloro-4-(4-aminophenoxy)phenyl]methane, bis[3,5-dimethyl-4-(4-aminophenoxy)phenyl]methane, bis[4-(4-aminophenoxy)phenyl]sulfone, and 2,2-bis[4-(4-aminophenoxy)phenyl]perfluoropropane, among which p-phenylenediamine, m-phenylenediamine, 4,4′-diaminodiphenylmethane, 4,4′-diaminodiphenyl ether, 1,4-bis(3-aminophenoxy)benzene, 1,4-bis(4-aminophenoxy)benzene, 2,2-bis[4-(4-aminophenoxy)phenyl]propane, and 2,2-bis[3-methyl-4-(4-aminophenoxy)phenyl]propane are preferred.

The polyimidesilicone resin (a) preferably has a phenolic hydroxyl group for good adhesion. The phenolic hydroxyl group can be introduced into the polyimidesilicone resin by using a diamine compound having a phenolic hydroxyl group as the diamino compound of the formula (4). Examples of such diamine compound are as shown below.

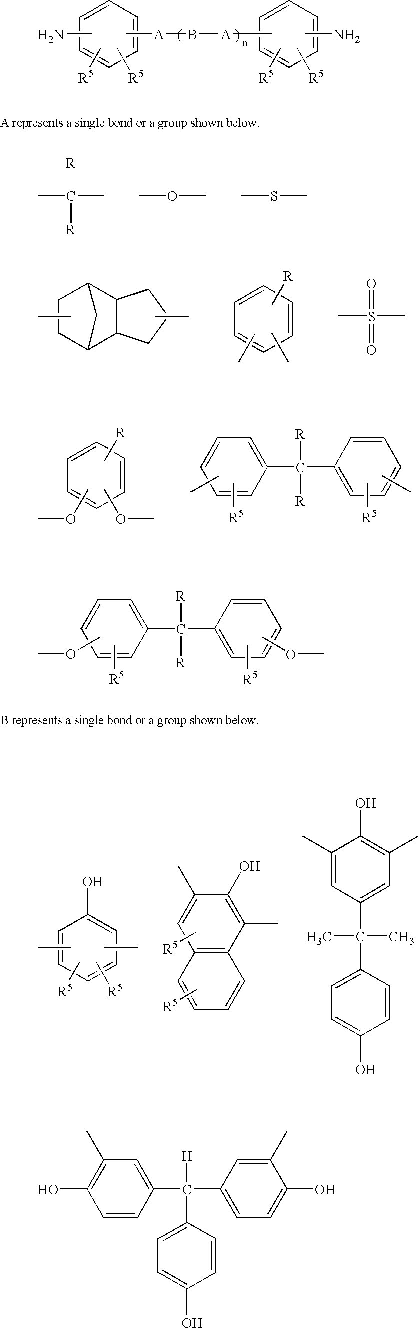

In the above formulas, R⁵ is a hydrogen atom, a halogen atom such as fluorine, bromine or iodine atom, or a substituted or unsubstituted monovalent C₁₋₈ hydrocarbon group such as an alkyl, alkenyl, alkynyl, trifluoromethyl or phenyl group, and n is an integer of from 0 to 5. The moieties A and B, respectively, may be a mixture of two or more of the groups. R is a hydrogen atom, a halogen atom, or a substituted or unsubstituted monovalent hydrocarbon group.

Examples of R⁵ and R in the above formulas include the groups presented for R³ and R⁴ above and alkenyl groups such as ethynyl, propynyl, butynyl and hexynyl groups.

The diamine compound having a phenolic group is used in an amount of from 5 to 60 wt %, particularly of from 10 to 40 wt % based on a total weight of the diamine compound. If the amount is below the aforesaid lower limit, adhesion strength of a composition may be lower. If the amount is above the aforesaid upper limit, an adhesive layer may have insufficient strength.

A monoamine having a phenolic hydroxyl group can be also used. Examples of the monoamine compounds are as shown below.

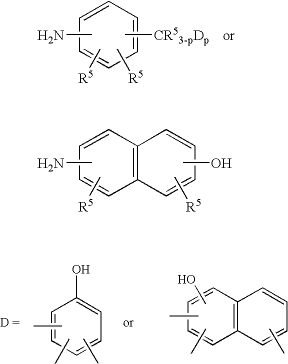

In the above formulas, R⁵ is as defined above. D may be a mixture of the two groups and p is an integer of from 1 to 3.

The polyamic acid is prepared by dissolving the aforesaid starting materials in a solvent, which is then subjected to a reaction typically at a temperature of 80° C. or lower, preferably from 0 to 40° C. in an inert atmosphere. The polyamic acid obtained is heated at a temperature of from 100 to 200° C., preferably from 150 to 200° C., whereby the amide of the carboxylic acid is dehydrated to effect ring closure to form an intended polyimide resin.

The organic solvent used in the above reaction need not completely dissolve the aforesaid starting materials as far as it is inactive to the polyamic acid obtained. Examples of the solvent include tetrahydrofuran, 1,4-dioxane, cyclopentanone, cyclohexanone, γ-butylolactone, N-methylpyrrolidone, N,N-dimethylacetamide, N,N-dimethylformamide, and dimethylsulfoxide, among which aprotic polar solvents are preferred, particularly N-methylpyrrolidone, cyclohexanone, γ-butylolactone and mixtures thereof are preferred.

Preferably, azeotropic solvent such as toluene and xylyene are used to facilitate the dehydration and ring closure reaction. The dehydration and ring closure reaction can be performed at a low temperature using a mixture of acetic acid anhydride with pyridine.

In order to adjust molecular weight of the resins, it is possible to add anhydrous dicarboxylic acids, such as maleic anhydride and phthalic anhydride, and/or monoamines, such as aniline, n-butylamine, and the aforesaid monoamine having a phenolic hydroxyl group, with proviso that the anhydrous dicarboxylic acid is added, in general, in amount of from 0 to 2 moles per 100 moles of tetracarboxylic acid dianhyride, and the monoamine may be added, in general, in an amount of 0 to 2 moles per 100 moles of diamine.

The epoxy resin used in the present invention (b) preferably has at least two epoxy groups per molecule. Examples of the epoxy resin include diglycidyl ethers of bis(4-hydroxyphenyl)methane and 2,2′-bis(4-hydroxyphenyl)propane or halides thereof, and polycondensates thereof (so-called bisphenol F type epoxy resins and bisphenol A type epoxy resins); butadiene diepoxide; vinylcyclohexene dioxide; diglycidyl ether of resorcin; 1,4-bis(2,3-epoxypropoxy)benzene; 4,4′-bis(2,3-epoxypropoxy)diphenyl ether; 1,4-bis(2,3-epoxypropoxy)cyclohexene; bis(3,4-epoxy-6-methylcyclohexylmethyl)adipate; epoxy glycidyl ethers or polyglycidyl esters obtained by condensation of 1,2-dihydroxybenzene (or resorcinol), polyhydric phenols or polyhydric alcohols with epichlorohydrin; epoxy novolac resins (i.e., novolac type epoxy resins) obtained by condensation of novolac type phenolic resins (or halogenated novolac type phenolic resins), such as phenol novolac and cresol novolac, with epichlorohydrin; polyolefins epoxidized by peroxidation process; epoxidized polybutadiene; naphthalene ring-containing epoxy resins; and epoxy resins of biphenyl type, phenol aralkyl type, biphenyl aralkyl type, and cyclopentadiene type.

The epoxy resin (b) is contained in the composition in an amount of from 5 to 200 parts by weight, preferably from 10 to 100 parts by weight, relative to 100 parts by weight of the polyimide resin (a). If the content of the epoxy resin is below the aforesaid lower limit, adhesion strength may be poor. If the content is above the aforesaid upper limit, a cured adhesive layer may have insufficient flexibility.

A mono-epoxy compound can be used in combination with the epoxy resin having at least two epoxy groups in a molecule. Exemplary mono-epoxy compounds include styrene oxide, cyclohexene oxide, propylene oxide, methyl glycidyl ether, ethyl glycidyl ether, phenyl glycidyl ether, allyl glycidyl ether, octylene oxide and dodecene oxide, and mixtures thereof.

The present composition can comprise a curing agent for epoxy resin (c). Any known curing agent may be used and examples thereof include triphenylphosphine, phosphonium tetraphenyl borate, tetraphenyl phosphonium tetraphenyl borate, and the following compounds.

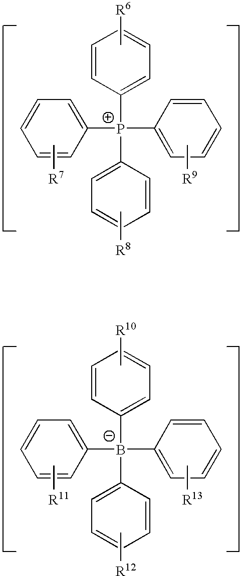

In the formula, R⁶ to R¹³ are the same with or different from each other and represent a hydrogen atom, a halogen atom, such as fluorine, bromine, and iodine, or an alkoxyl group having 1 to 8 carbon atoms such as alkyl, alkenyl, alkynyl, methoxy, ethoxy, propoxy, isopropoxy, and butoxyl groups, a substituted or unsubstituted monovalent hydrocarbon group, such as trifluoromethyl and phenyl groups.

Examples of the amine catalysts include dicyandiamide and imidazole compounds such as 2-methylimidazole, 2-ethyl-4-methylimidazole, 1-cyanoethyl-2-methylimidazole, and 2-phenyl-4,5-dihydroxymethylimidazole.

The curing catalyst for epoxy resin in the present invention may be used alone or as a mixture of two or more of the above-described catalysts. The epoxy resin curing catalyst (c) is contained in the composition in an amount of from 0.1 to 10 parts by weight, preferably from 0.5 to 5 parts by weight, relative to 100 parts by weight of (b).

The present composition can comprise a curing agent for epoxy resin. Any known curing agent, or mixtures thereof, for epoxy resins may be used, and mention may be made of, for example, amine compounds such as diethylenetriamine, triethylenetetramine, diethylaminopropylamine, N-aminoethylpiperazine, bis(4-amino-3-methylcyclohexyl)methane, meta-xylylenediamine, menthanediamine, and 3,9-bis(3-aminopropyl)-2,4,8,10-tetraoxaspiro(5,5)undecane; modified aliphatic polyamines such as epoxy resin-diethylenetriamine adduct, amine-ethylene oxide adduct, and cyanoethylated polyamine; phenolic resins having at least two phenolic hydroxyl groups per molecule, such as bisphenol A, trimethylol allyloxyphenol, phenol novolac resins having a low degree of polymerization, epoxidized or butylated phenolic resins, and phenolic resins available under the trade names of “Super Beckacite 1001”, ex Japan Reichhold Chemical Co., Ltd., “Hitanol 4010”, ex Hitachi Ltd., “Scado form L. 9”, ex Scado Zwoll, Netherlands, and “Methylon 75108”, ex General Electric Company; carbon resins available under the trade names of “Beckamine P. 138”, ex Japan Reichhold Chemical Co., Ltd., “Melan”, ex Hitachi Ltd., and “U-Van 10R”, ex Toyo Koatsu Kogyo Co., Ltd.; amino resins such as melamine resins and aniline resins; polysulfide resins having at least two mercapto groups per molecule represented by the formula: HS(C₂H₄OCH₂OC₂H₄SS)ₙC₂H₄OCH₂OC₂H₄SH, wherein n is an integer of 1 to 10; and organic acids and acid anhydrides thereof such as phthalic anhydride, hexahydrophthalic anhydride, tetrahydrophthalic anhydride, pyromellitic anhydride, methylnadic acid, dodecylsuccinic anhydride, and chlorendic anhydride. Of the aforesaid curing agents, phenolic resins are desired because they imparts good molding property and humidity resistance to the present composition as well as they are non-toxic and relatively less costly. The curing agent described above may be used alone or as a mixture of two or more of them, depending on curing efficiency. An amount of the agent to be used is not limited to a particular range as far as desired properties are obtained.

The curing agent is contained in the composition in an amount of from 1 to 100 parts by weight, preferably from 5 to 50 parts by weight, relative to 100 parts by weight of the epoxy resin (b). If the content of the epoxy resin is below the aforesaid lower limit, it is difficult to cure the present composition well. If the content is above the aforesaid upper limit, the process is not only disadvantageous economically but also the epoxy resin is diluted and curing takes a prolonged time, which results in worse mechanical properties of the cured product.

When the polyimide resin (a) contains phenolic hydroxyl groups, its amount should be taken into consideration to determine an amount of the phenolic resin curing agent in order to obtain desired cured product of the epoxy resin (b). In curing process, epoxy groups react with phenolic hydroxyl groups. If there are not sufficient amount of the epoxy groups, sufficient adhesion strength to a substrate may not be attained. If there are too much epoxy groups, a flexible adhesive layer may not be obtained due to large modulus of elasticity of the epoxy resin. Preferably, an equivalent ratio of epoxy groups to phenolic hydroxyl groups is in the range of from 0.7 to 1.3, more preferably from 0.8 to 1.2.

In addition, optional components may be added to the present composition, for example, filler such as silica fine powder, alumina, titanium oxide, carbon black, silica fine particles, and electrically conductive particles, inorganic or organic pigments, colorants such as dies, wetting aids, antioxidants, and thermal stabilizers as required for intended use.

The silica fine powder are preferably spherical and have an average diameter of 0.1 μm to 10 μm, preferably 0.5 μm to 5 μm, and the greatest particle diameter of 20 μm or less. The silica fine powder are preferably surface treated with an organosilicon compound having an epoxy group. Examples of the silica particles include SE-2050, SC-2050, SE-1050, SO-E1, SO-C1, SO-E2, SO-C2, SO-E3, SO-C3, SO-E5, SO-C5, ex Admatechs Co., Ltd, and mixtures thereof. The silica particles are contained in an amount of from 20 to 70 wt %, and particularly from 30 to 65 wt %, relative to the total weight of the composition.

Preferably, the present composition comprises composite silicone rubber fine particles together with silica fine powder. The composite silicone rubber may be prepared by a known method described, for example, in Japanese Patent Application Laid-open No. 7-196815. That is, adding alkaline substance or alkaline aqueous solution and organotrialkoxysilane to an aqueous dispersion of spherical silicone rubber fine powder having an average diameter of from 0.1 to 10 μm and, then, hydrolyzing and polymerizing the organotrialkoxysilane on the spherical silicone rubber surface followed by drying. Examples of the composite silicone rubber fine particles include KMP-600, KMP-605, and X-52-7030, all available from Shin-Etsu Chemical Co., Ltd. A mixture of these particles can be used. The composite silicone fine particles have an average particle diameter of from 0.1 to 10 μm, preferably from 0.1 to 5 μm. If the diameter is larger than the aforesaid upper limit, a surface of the adhesive layer of the present invention may not be smooth. The composite silicone particles are used in an amount of from 5 to 30 wt %, preferably from 10 to 20 wt % based on a total weight of the composition. Outside the aforesaid range, the adhesive layer may be difficult to be pressure bonded at a low temperature and a low pressure. Moreover, cured adhesive composition may have larger coefficient of linear expansion.

The composition for the adhesive layer can be prepared by mixing the polyimide resin (a), the epoxy resin (b), the epoxy resin curing catalyst (c), and optional components as needed, in the usual manner.

The dicing and die bonding tape of the present invention can be prepared by the following method:

(i) The PSA layer (A) is formed on substrate 1 by applying the aforesaid PSA composition to substrate 1 followed by heating to dry and cure the composition. The heating temperature is usually of from 60 to 120° C., though can be varied depending on heat resistance of plastic film substrate 1. The film thus obtained is hereinafter referred to as a PSA film (A).

(ii) Separately, the PSA layer (B) is prepared by applying the aforesaid PSA composition, preferably a silicone PSA composition, on substrate 3 followed by heating to dry and cure the composition. The heating temperature is usually of from 60 to 120° C., though can be varied depending on heat resistance of plastic film substrate 3. The film thus obtained is hereinafter referred to as a PSA film (B).

Subsequently, adhesive layer 5 is formed by applying the adhesive composition, which preferably comprises the polyimide resin (a), the epoxy resin (b), and the epoxy resin curing catalyst (c), on substrate 6 and heating to dry the composition. The obtained film thus obtained is hereinafter referred to as an adhesive film. The substrate 6 may be polyethylene, polypropylene, polyester, polyamide, polyimide, polyamideimide, polyetherimide, polytetrafluoroethylene, paper, and metal foil. These substrates may be surface treated with a release agent. The substrate 6 may be peeled off from the adhesive layer 5 at anytime before a dicing process. Preferably, a polyester film having a thickness of from 4 to 50 μm is used.

The adhesive layer 5 usually has a thickness of from 10 to 100 μm. The drying may be performed at a temperature of from room temperature to 200° C., particularly from 80 to 150° C., for one minute to one hour, particularly 3 to 10 minutes.

The PSA film (B) prepared as described above is cut in the form of a disk having an outer diameter smaller than an inner diameter of a dicing flame. The rear surface of the PSA film (B), i.e., the uncoated surface of the substrate 3, is superimposed on the PSA layer (A). On the surface of the PSA layer (B) of the film obtained, the adhesive layer 5 of the adhesive film, which has been cut in about the same circular shape as the PSA film (B), is pressure bonded, whereby the dicing and die bonding tape of the present invention is obtained. The adhesive layer 5 may not have a circular shape as far as it can fix a silicon wafer. The PSA film (B) may not have a circular shape either, as far as it can be fit in a dicing flame and can fix the adhesive layer 5 during dicing process.

The dicing and die bonding tape of the present invention is used by peeling off the substrate 6 of the adhesive film, and pressure bonding, or thermocompression bonding, the exposed adhesive layer 5 to a silicon wafer and the PSA layer (A) to a dicing flame, respectively. The heating temperature of the thermocompression bonding may range from 40 to 120° C. Then, the tape is fixed to a dicing machine. After dicing the wafer, chips with diced adhesive layer 5 attached thereto are picked up, causing the adhesive layer 5 to be peeled from the PSA layer (B). The adhesive layer 5 attached to a diced chip is pressure bonded to a substrate and, then, heat cured. Temperature of the curing is selected according to composition of adhesive layer, and usually ranges from 120 to 250° C. Alternatively, the adhesive layer may be cured after wire bonding and molding of an encapsulation resin simultaneously with curing of the molded resin at a temperature of from 150 to 250° C.

Determination Methods

Methods for determining adhesion strength and other properties used in the present invention are as follows.

Adhesion Strength of the Adhesion Strength of the Film (A) to a Dicing Frame

A pressure sensitive adhesive film (A) was cut into a tape with a width of 10 mm. A pressure sensitive adhesive layer of the tape was pressure bonded to a dicing frame for an 8-inch wafer, ex Disco Corporation, to fix. The test body thus obtained was allowed to stand in the atmosphere of a constant temperature of 25±2° C. and a constant relative humidity of 50±5% for 30 minutes or more. Then, a small part of one end of the pressure sensitive adhesive film was peeled from the dicing flame and 180-degree peel force was measured at a pulling rate of 300 mm/minute. The force measured was converted into that for a width of 25 mm to obtain adhesion strength (A) shown in Table 2.

Adhesion Strength of the Pressure Sensitive Adhesive Film (B) to the Adhesive Layer

A dicing and die bonding tape was cut into a tape with a width of 25 mm. The substrate film on the adhesive layer was peeled from the tape, and the exposed adhesive layer surface was thermocompression bonded to a glass plate having a thickness of 2.0 mm and a width of 50 mm at 80° C. and 0.01 MPa for 10 seconds. The test sample obtained was allowed to stand under a constant temperature of 25±2° C. and a relative humidity of 50±5% for 30 minutes or more. Then, a small part of one end of the pressure sensitive adhesive film (B) was peeled from the adhesive layer and 180-degree peel force was measured at a pulling rate of 300 mm/minute. The adhesion strength (B) in Table 2 represents the values as obtained in the above method.

Glass Transition Temperature and Linear Expansion Coefficient

An adhesive film obtained was heated at a temperature of 175° C. for 2 hours for curing. A film of 20 mm×5 mm×50 μm was cut out from the adhesive film to determine a glass transition temperature, and a linear expansion coefficient with a thermomechanical analyzer, TMA-2000, ex ULVAC Inc., in a tension mode under the following conditions: chuck distance: 15 mm; determination temperature: 25-300° C.; temperature rise rate: 5° C./minute; and measuring load: 3 g.

Young's Modulus

An adhesive film obtained as described above was cured at a temperature of 175° C. for 2 hours. A piece of film of 40 mm×10 mm×50 μm was cut out to determine Young's modulus using a dynamic viscoelastometry instrument. Determination was made in a tension mode under the following conditions: chuck distance: 10 mm; determination temperature: 25° C.; and frequencies: 1 Hz. Heat curing temperature was set depending on each adhesive composition.

Adhesion Strength

A dicing and die bonding tape was thermocompression bonded to a silicon wafer having a diameter of 6 inches and a thickness of 450 μm and the wafer was diced into chips of 2 mm×2 mm. The silicon chips with the adhesive layer attached on their back sides were picked up and thermocompression bonded at 150° C. and at 0.1 MPa for 2 seconds to a 10 mm×10 mm BT substrate, whereon a photoresist, AUS 303, ex Unitechno Inc., had been applied and cured, and to a silicon substrate, respectively. The thus-obtained test specimens were heated at a temperature of 175° C. for 2 hours for curing the adhesive layer to obtain test specimens for adhesion strength measurement. The shear adhesion strength at 240° C. was determined with a bondtester, 4000 PSY, ex DAGE Group.

Adhesion Strength after Moisturizing and Heating

The test specimens for Adhesion Strength test prepared as described above were allowed to stand under the condition of 85° C./60% RH for 168 hours, and then passed through a reflow furnace at 260° C. three times. Then shear adhesion strength was determined at 240° C.

Dicing and Chip Picking Up Test

The substrate film on the adhesive layer of a dicing and die bonding tape was peeled off and a wafer having a diameter of 8 inches and a thickness of 50 μm was thermocompression bonded to the exposed adhesive layer using a film mounter, FM-114, ex Technovision Inc., and a dicing frame, for instance, from Disco Corporation, was thermocompression bonded to the pressure sensitive adhesive layer (A) at 60° C. with a rolling pressure of 2 kg. This was diced into chips of 10 mm×10 mm and the chips were picked up with a die bonder instrument, BESTEM-D02-Type C, ex NEC Machinery Corporation. Each dicing and die boding tape is rated as “A” when no chip is flown off or scattered in the dicing process, otherwise as “B”; is rated as “A” when chips are picked up without problems, otherwise as “B”; and is rated as “A” when no die crack occurred, otherwise as “B” as shown in Table 2.

Dicing conditions

Instrument: DAD 341 from Disco Corporation

Blade: ZHT445 2050SE 27EEE

Rotation: 30,000 rpm

Dicing speed: 30 mm/sec

Adhesion to a Dicing Frame

In the above dicing and chip pick up test, adhesion between a dicing frame and a dicing and die bonding tape was visually observed. A tape which kept sticking to the dicing flame during the test was rated as “A”, otherwise rated as “B”.

### EXAMPLES

The present invention will be elucidated with reference to the Examples and the Comparative Examples, but shall not be limited thereto.

Synthesis of Polyimide Resin—I

In a 1 litter separable flask equipped with a reflux condenser, a stoppered 25 ml quantitative water receiver connected to the reflux condenser, a thermometer, and a stirrer, were added 32.2 parts by weight of 3,3′,4,4′-benzophenone tetracarboxylic acid dianhydride and 150 parts by weight of 2-methylpyrrolidone as a solvent, and stirred to disperse the acid dianhydride. In the above dispersion, was added dropwise a dispersion of 51.28 party by weight of the dimethyldiaminopolysiloxane-1 having an amine equivalent of 641 represented by the following formula 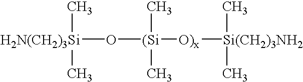
in 50 parts by weight of 2-methylpyrrolidone, and then subjected to reaction at a room temperature for 1 hour under stirring to prepare an oligomer of an amic acid, which is rich in acid anhydride.

Then, in the solution of the amic acid oligomer thus obtained, were added dropwise 29.68 parts by weight of aromatic diamine having phenolic hydroxyl groups represented by the following formula (phenoldiamine-1),

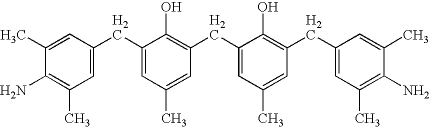

and 140 parts by weight of 2-methylpyrrolidone, and stirred at room temperature for 16 hours to prepare a polyamic acid solution. Then, 80 ml of toluene was added and then the reaction system was heated and refluxed at 180° C. for 4 hours. It was confirmed that a prescribed amount of water was collected and no water was distilled off any more and then toluene was removed at 180° C. while removing the distillate collected in the quantitative water receiver. After the completion of the reaction, the obtained reaction mixture was added dropwise into a large excess amount of methanol to precipitate the polymer. The resulting polymer was dried under reduced pressure to obtain the polyimidesilicone resin-I having a phenolic hydroxyl group. The IR absorption spectra of the resulting resin did not show absorption based on polyamic acid that indicates the presence of the unreacted functional group, but instead showed absorption at 1780 cm⁻¹ and 1720 cm⁻¹ based on imide groups and absorption around 3500 cm⁻¹ based on a phenolic hydroxyl group. The weight average molecular weight was 56,000, reduced to polystyrene, as determined by gel permeation chromatography (GPC) using tetrahydrofuran as a solvent.

Synthesis of Polyimide Resin —II

The same procedures as those in the above synthesis of polyimide silicone I were repeated except that use was made of 44.4 parts by weight of 6FDA (2,2-bis(3,4-dicarboxyphenyl)hexafluoropropane instead of 3,3′,4,4′-benzophenone tetracarboxylic acid dianhydride; 56.98 parts by weight of dimethyldiaminopolysiloxane-2 (diaminopolysiloxane having a similar structure as dimethyldiaminopolysiloxane-1 but with a different amine equivalent of 407) instead of dimethyldiaminopolysiloxane-1; 12.3 parts by weight of BAPP (2,2-bis[4-(4-aminophenoxy)phenyl]propane) as aromatic diamine in stead of the phenoldiamine-1; and total 340 parts by weight of 2-methylpyrrolidone, to obtain a polyimidesilicone resin-II not having a phenolic hydroxyl group in its backbone. The molecular weight was 72,000.

Preparation of Adhesive Compositions

Forty parts by weight of polyimide resin I or II was dissolved in 60 parts by weight of cyclohexanone. To the solution, each epoxy resin indicated in Table 1 was added in an amount (solid content) indicated therein to obtain adhesive compositions I-IV.

Preparation of Adhesive Films

Each adhesive composition thus obtained was applied in such an amount to form about 40 μm-thick layer on a 50-μm thick PET film coated with a fluorinated silicone release agent. The film was heat dried at 80° C. for 30 minutes to form adhesive film. Adhesive films I-IV were prepared from adhesive compositions I-IV, respectively.

Preparation of Pressure Sensitive Adhesive Silicone Compositions for PSA Layer (A)

### Preparation Example 1

A pressure sensitive adhesive silicone composition-I was prepared from 108.3 parts by weight of a 60 wt % toluene solution of methylpolysiloxane resin composed of (CH₃)₃SiO_{1/2} units and Sio₂ units in a molar ratio of 1.1:1; 35 parts by weight of a raw rubber-like dimethylpolysiloxane having a polymerization degree of 2,000, and vinyl groups at terminal and in side chains in an amount of 0.002 mole per 100 g of the dimethylpolysiloxane; and 142.4 parts by weight of toluene, 0.32 parts by weight of an organopolysiloxane compound having hydrogen atoms bonded to silicon atoms represented by the following structure; a solution of chloroplatinic acid modified with 2-ethylhexanol in an amount of 40 ppm as platinum metal; and 0.15 parts by weight of 3-methyl-1-butyn-3-ol as a reaction retarder.

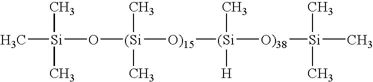

### Preparation Example 2

A pressure sensitive adhesive silicone composition-II was prepared in the same manner as in Preparation Example 1 from 75 parts by weight of a 60 wt % toluene solution of methylpolysiloxane resin composed of (CH₃)₃Sio_{1/2} units and SiO₂ units in a molar ratio of 1.1:1; 55 parts by weight of a raw rubber-like dimethylpolysiloxane having a polymerization degree of 2,000, and vinyl groups at terminal and in side chains in an amount of 0.002 mole per 100 g of the dimethylpolysiloxane; and 155.7 parts by weight of toluene, 0.51 parts by weight of an organopolysiloxane compound having hydrogen atoms bonded to silicon atoms represented by the above structure; a solution of chloroplatinic acid modified with 2-ethylhexanol in such an amount that platinum content is 40 ppm; and 0.15 parts by weight of 3-methyl-1-butyn-3-ol as a reaction retarder.

Preparation of Pressure Sensitive Adhesive Silicone Composition for PSA Layer (B)

### Preparation Example 3

A pressure sensitive adhesive silicone composition-III was prepared from 33.33 parts by weight of a 60 wt % toluene solution of methylpolysiloxane resin composed of (CH₃)₃SiO_{1/2} units and SiO₂ units in a molar ratio of 1.1:1; 80 parts by weight of a raw rubber-like dimethylpolysiloxane having a polymerization degree of 2,000, and vinyl groups at terminal and in side chains in an amount of 0.002 mole per 100 g of the dimethylpolysiloxane; and 172 parts by weight of toluene were solved to obtain a homogeneous mixture. To this mixture were added 0.68 parts by weight of an organopolysiloxane compound having hydrogen atoms bonded to silicon atoms represented by the following structure and 0.24 parts by weight of 3-methyl-1-butyn-3-ol as a reaction retarder. Then a solution of chloroplatinic acid modified with 2-ethylhexanol was added in such an amount that platinum content is 40 ppm.

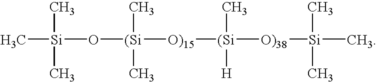

### Preparation Example 4

A pressure sensitive adhesive silicone composition-IV was prepared in the same manner as in Preparation Example 3 from 41.67 parts by weight of a 60 wt % toluene solution of methylpolysiloxane resin composed of (CH₃)₃SiO_{1/2} units and SiO₂ units in a molar ratio of 1.1:1; 75 parts by weight of a raw rubber-like dimethylpolysiloxane having a polymerization degree of 2,000, and vinyl groups at terminal and in side chains in an amount of 0.002 mole per 100 g of the dimethylpolysiloxane; 169 parts by weight of toluene; 0.68 parts by weight of an organopolysiloxane compound having hydrogen atoms bonded to silicon atoms represented by the above structure; 0.24 parts by weight of 3-methyl-1-butyn-3-ol as a reaction retarder; and a solution of chloroplatinic acid modified with 2-ethylhexanol in such an amount that platinum content is 40 ppm.

### Preparation Example 5

A pressure sensitive adhesive silicone composition-V was prepared in the same manner as in Preparation Example 3 from 16.66 parts by weight of a 60 wt % toluene solution of methylpolysiloxane resin composed of (CH₃)₃SiO_{1/2} units and SiO₂ units in a molar ratio of 1.1:1; 90 parts by weight of a raw rubber-like dimethylpolysiloxane having a polymerization degree of 2,000, and vinyl groups at terminal and in side chains in an amount of 0.002 mole per 100 g of the dimethylpolysiloxane; 180 parts by weight of toluene, 0.77 parts by weight of an organopolysiloxane compound having hydrogen atoms bonded to silicon atoms represented by the above structure, 0.24 parts by weight of 3-methyl-1-butyn-3-ol as a reaction retarder, and a solution of chloroplatinic acid modified with 2-ethylhexanol in such an amount that platinum content is 40 ppm.

### Preparation Example 6

A pressure sensitive adhesive silicone composition-VI was prepared in the same manner as in Preparation Example 3 from 58.33 parts by weight of a 60 wt % toluene solution of methylpolysiloxane resin composed of (CH₃)₃SiO_{1/2} units and SiO₂ units in a molar ratio of 1.1:1; 65 parts by weight of a raw rubber-like dimethylpolysiloxane having a polymerization degree of 2,000, and vinyl groups at terminal and in side chains in an amount of 0.002 mole per 100 g of the dimethylpolysiloxane; 162.4 parts by weight of toluene, 0.50 parts by weight of an organopolysiloxane compound having hydrogen atoms bonded to silicon atoms represented by the above structure, 0.24 parts by weight of 3-methyl-1-butyn-3-ol as a reaction retarder, and a solution of chloroplatinic acid modified with 2-ethylhexanol in such an amount that platinum content is 40 ppm.

Preparation of Pressure Sensitive Adhesive Film (A)

Pressure sensitive adhesive silicone films I and II were prepared by applying pressure sensitive adhesive silicone compositions I and II, respectively, on a 100 μm thick unstretched polyethylene (LDP) film whose surface had been corona-treated, and drying at a temperature of 100° C. for 10 minutes to form pressure sensitive adhesive silicone layers I and II having a thickness of 15 μm.

Commercially Available Pressure Sensitive Adhesive Film (A)

Commercially available pressure sensitive adhesive film, T-80LW, ex Toyo Adtec, and VD-8, ex Nitto Denko were used.

Preparation of Pressure Sensitive Adhesive Film (B)

Pressure sensitive adhesive films III to VI were prepared by applying pressure sensitive adhesive silicone compositions III to VI, respectively, on a 12 μm thick polyethylene terephthalate (PET) film and heating at a temperature of 100° C. for 10 minutes to form pressure sensitive adhesive silicone layers having a thickness of 15 μm. Pressure sensitive adhesive silicone films VII and VIII were prepared in the same manner as above by applying the pressure sensitive adhesive silicone composition III on 4 μm and 75 μm thick PET films, respectively, followed by heating.

Preparation of Dicing and Die Bonding Tapes (Examples 1-6, Reference Examples 1-4, and Comparative Example 1)

Dicing and die bonding tapes were prepared adhesive films, a pressure sensitive adhesive films (A), and a pressure sensitive adhesive films (B) in combinations as shown in Table 2. Each pressure sensitive adhesive film (B) was cut into a piece of film to be fit in a dicing frame and, then, the backside of the substrate of the film (B) was bonded to a pressure sensitive adhesive layer of a pressure sensitive adhesive film (A). Then, the pressure sensitive adhesive layer (B) was bonded to the adhesive layer of the adhesive film, which had been cut into a circular shape with an approximately same outer diameter as that of a wafer, whereby a dicing and die bonding tape was obtained. The bonding was performed by pressure bonding at 2 kg of load, using a roll having a width of 300 mm. In Comparative Example 1, a dicing and die bonding tape was prepared by attaching pressure sensitive adhesive film VI alone to an adhesive film.

Glass transition temperature after curing, linear expansion coefficient, and Young's modulus were measured on adhesive films. Adhesion strength to a dicing flame was measured on the pressure sensitive adhesive film (A). Adhesion strength between an adhesive layer and pressure sensitive adhesive layer (B), thermocompression property, adhesion strength, adhesion strength after moisturizing and heating, dicing property and chip pick up property were determined/tested, according to the aforementioned methods. The results are shown in Tables 1 and 2.

TABLE 1

| Adhesive composition | I | II | III | IV |
|---|---|---|---|---|
| (a) Polyimide resin | | | | |
| I | 50 | 20 | | 20 |
| II | | | 80 | 10 |
| (b) Epoxy compound | | | | |
| b 1 | | 19 | 38 | 19 |
| b 2 | 27.5 | | | |
| b 3 | 20 | | | 19 |
| (c) Catalyst | | | | |
| Dicyandiamide | | 1 | 1 | 1 |
| 2PHZ | 2.5 | | | |
| Spherical silica fine powder | | 50 | | 40 |
| Silicone rubber powder | | 10 | | 10 |
| Property of adhesive film | | | | |
| Young's modulus (MPa) | 1890 | 3160 | 1610 | 3020 |
| Tg(° C.) | 118 | 115 | 108 | 110 |
| Linear expanstion coefficient α1 (ppm) | 117 | 55 | 120 | 80 |
| Linear expanstion coefficient α2 (ppm) | 200 | 145 | 211 | 168 |

The resins and other materials shown in Table 1 are as follows:
b1: RE-310S, ex Nippon Kayaku.
b2: RE-600N, ex Nippon Kayaku.
b3: EOCN-102S, ex Nippon Kayaku.
Dicyandiamide: ex Japan Epoxy Co., Ltd.
2PHZ: 2-phenyl-4,5-dihydroxymethylimidazole, ex Shikoku Chemicals Corporation.
Spherical silica fine powder: SE-2050 MA, ex Admatechs Co., Ltd. (average particle size: 0.5 μm).

Silicone rubber powder: X-52-7030, ex Shin-Etsu Chemical Co., Ltd. (average particle size: 0.7 μm).

TABLE 2

| | | Example | | | | | | Reference Example | | | | Com. Ex.* |
|---|---|---|---|---|---|---|---|---|---|---|---|---|
| | | 1 | 2 | 3 | 4 | 5 | 6 | 1 | 2 | 3 | 4 | 1 |
| Adhesive film | | I | II | III | IV | II | IV | II | IV | II | IV | II |
| PSA** film (B) | | III | III | III | III | IV | VII | III | V | VI | VIII | VI |
| PSA film (A) | | I | T-80LW | T-80LW | VD-8 | VD-8 | I | II | I | I | VD-8 | |
| Adhesion strength (A) (N/25 mm) | | 2.2 | 0.65 | 0.65 | 1.2 | 1.2 | 2.2 | 0.48 | 2.2 | 2.2 | 1.2 | 0.17 |
| Adhesion strength (B) (N/25 mm) | | 0.2 | 0.18 | 0.14 | 0.17 | 0.42 | 0.23 | 0.16 | 0.03 | 0.64 | 0.15 | 0.64 |
| Flying off of chips in dicing process | | A | A | A | A | A | A | A | B | A | A | A |
| Chip pick up | | A | A | A | A | A | A | A | A | A | B | B |
| Die crack | | A | A | A | A | A | A | A | A | B | — | B |
| Adhesion to dicing frame | | A | A | A | A | A | A | B | A | A | A | A |
| Adhesion strength to | initial after moisturising | 5.2 | 11 | 4.9 | 8.2 | 11 | 8.2 | 11 | 8.2 | 11 | 8.2 | 11 |
| silicon substrate (MPa) | and heating | 4.8 | 9.5 | 4.4 | 7.1 | 9.5 | 7.1 | 9.5 | 7.1 | 9.5 | 7.1 | 9.5 |
| Adhesion strength to | initial after moisturising | 3.8 | 9.7 | 3.4 | 7.5 | 9.7 | 7.5 | 9.7 | 7.5 | 9.7 | 7.5 | 9.7 |
| BT substrate (MPa) | and heating | 3.5 | 8.5 | 3.0 | 7.2 | 8.5 | 7.2 | 8.5 | 7.2 | 8.5 | 7.2 | 8.5 |

*Comparative Example
**Pressure sensitive adhesive

The tapes of Examples did not cause chips to fly off and allowed to pick up chips without cracking.

On the other hand, the tape of Comparative Example 1 has a PSA layer 1 only. It had too low adhesion strength to the die flame, but had too high adhesion strength to the adhesive layer, causing die crack. The tape of Reference Example 1 had insufficient adhesion strength of the PSA layer (A) to the dicing flame. The tape of Referential Example 2 had insufficient adhesion strength of the PSA layer (B) to a wafer, so that it caused diced chips to fly off. The tape of Comparative Example 3, on the other hand, had too strong adhesion strength to a wafer to cause chips to crack. In the tape of Reference Example 4, the substrate of the PSA film (B) is 75 μm thick PET film which did not extend sufficiently for picking up diced chips.

1. A dicing and die bonding tape, comprising a substrate 1, a pressure sensitive adhesive layer (A) 2 superimposed on the substrate 1, a substrate 3 superimposed on the pressure sensitive adhesive layer (A) 2, a pressure sensitive adhesive layer (B) 4 superimposed on the substrate 3, and an adhesive layer 5 super imposed on the pressure sensitive adhesive layer (B) 4, said dicing and die bonding tape having an adhesion strength between the pressure sensitive adhesive layer (A) 2 and a dicing flame of 0.6 N/25 mm or larger, and an adhesion strength between the pressure sensitive adhesive layer (B) 4 and the adhesive layer 5 of from 0.05 to 0.5 N/25 mm.

2. The dicing and die bonding tape according to claim 1, wherein the adhesion strength between the pressure sensitive adhesive layer (A) 2 and the dicing flame is 0.8 N/25 mm or larger and an adhesion strength between the pressure sensitive adhesive layer (B) 4 and the adhesive layer 5 ranges from 0.1 to 0.4 N/25 mm.

3. The dicing and die bonding tape according to claim 1 or 2, wherein the pressure sensitive adhesive layer (B) 4 has been prepared from a pressure sensitive adhesive silicone composition, and the adhesive layer 4 has been prepared from a composition comprising (a) a polyimide silicone resin, (b) an epoxy resin, and (c) an epoxy resin curing agent.

4. The dicing and die bonding tape according to claim 3, wherein the polyimide silicone resin (a) has a phenolic hydroxyl group.

5. The dicing and die bonding tape according to claim 3 wherein the pressure sensitive adhesive silicon composition comprises a linear organopolysiloxane having a vinyl group, an organopolysiloxane copolymer resin, an organohydrogenpolysiloxane, and a platinum group metal catalyst.

6. The dicing and die bonding tape according to claim 1, wherein the substrate 1 is composed of a polyethylene or propylene film, and the substrate 3 is composed of a polyester film.

7. The dicing and die bonding tape according to claim 6, wherein the substrate 3 has a thickness of from 4 to 50 μm.
